(19) United States
(12) Patent Application Publication
(10) Pub. No.: US 2026/0059859 A1
(43) Pub. Date: Feb. 26, 2026

(54) ELECTRONIC DEVICE

(71) Applicant: InnoLux Corporation, Miao-Li County (TW)

(72) Inventors: Chia-Hao TSAI, Miao-Li County (TW); Ming-Jou TAI, Miao-Li County (TW)

(21) Appl. No.: 19/283,410

(22) Filed: Jul. 29, 2025

(30) Foreign Application Priority Data
Aug. 23, 2024 (CN) 202411164981.3

(51) Int. Cl. H10D 86/40; H10D 86/60

(52) U.S. Cl. CPC H10D 86/441; H10D 86/411; H10D 86/423; H10D 86/60

(57) ABSTRACT

An electronic device includes a substrate having an active area, plural scan lines, plural data lines, plural first transistors, and plural second transistors. The scan lines and the data lines are disposed on the substrate, and are intersected to form plural pixels arranged in an array and disposed in the active area. The first transistors are disposed corresponding to the pixels of the active area, wherein each of the first transistors includes a first semiconductor. The second transistors are disposed corresponding to the pixels of the active area and alternately arranged with the first transistors, wherein each of the second transistors includes a second semiconductor. A material of the first semiconductor is different from that of the second semiconductor, and a distance between two adjacent first semiconductors is greater than that between two adjacent data lines.

### CROSS-REFERENCE TO RELATED APPLICATIONS

This application claims the benefits of the Chinese Patent Application Serial Number 202411164981.3, filed on Aug. 23, 2024, the subject matter of which is incorporated herein by reference.

### BACKGROUND

### Field of the Disclosure

The present disclosure relates to an electronic device and, more particularly, to an electronic device including different semiconductor materials.

### Description of Related Art

With the advance of technologies related to electronic devices, in order to meet consumer demands for electronic devices, electronic devices are now being developed towards compactness. As such, it is necessary to reduce the size of components inside electronic devices or to increase component density.

Therefore, there is an urgent need to provide an electronic device to alleviate and/or obviate the aforementioned defects.

### SUMMARY

The present disclosure provides an electronic device, which includes: a substrate having an active area; a plurality of scan lines disposed on the substrate and extending along a first direction; a plurality of data lines disposed on the substrate and extending along a second direction perpendicular to the first direction, wherein the scan lines and the data lines are intersected to form a plurality of pixels arranged in an array and disposed in the active area; a plurality of first transistors respectively disposed corresponding to the pixels of the active area, wherein each of the first transistors includes a first semiconductor; and a plurality of second transistors respectively disposed corresponding to the pixels of the active area and alternately arranged with the first transistors in the first direction, wherein each of the second transistors includes a second semiconductor, wherein a material of the first semiconductor is different from a material of the second semiconductor, and a distance between two adjacent first semiconductors is greater than a distance between two adjacent data lines in the first direction.

Other novel features of the disclosure will become more apparent from the following detailed description when taken in conjunction with the accompanying drawings.

### BRIEF DESCRIPTION OF DRAWINGS

FIG. 1A is a schematic top view of a portion of an electronic device according to an embodiment of the present disclosure;

FIG. 1B is a schematic cross-sectional view of the electronic device taking along line A-A′ and line B-B′ of FIG. 1A;

FIG. 2A is a schematic top view of a portion of an electronic device according to an embodiment of the present disclosure;

FIG. 2B is a schematic cross-sectional view of the electronic device taken along line C-C′ and line D-D′ of FIG. 2A;

FIG. 3A to FIG. 3C are schematic diagrams of a portion of an electronic device according to an embodiment of the present disclosure;

FIG. 4A is a schematic top view of a portion of an electronic device according to an embodiment of the present disclosure;

FIG. 4B is a schematic cross-sectional view of the electronic device taken along line A-A′ and line B-B′ of FIG. 4A;

FIG. 5A is a schematic top view of a portion of an electronic device according to an embodiment of the present disclosure;

FIG. 5B is a schematic cross-sectional view of the electronic device taken along line A-A′ and line B-B′ of FIG. 5A;

FIG. 6A is a schematic top view of a portion of an electronic device according to an embodiment of the present disclosure;

FIG. 6B is a schematic cross-sectional view of the electronic device taken along line A-A′ and line B-B′ of FIG. 6A;

FIG. 7A is a schematic top view of a portion of an electronic device according to an embodiment of the present disclosure;

FIG. 7B is a schematic cross-sectional view of the electronic device taken along line A-A′ and line B-B′ of FIG. 7A;

FIG. 8A is a schematic top view of a portion of an electronic device according to an embodiment of the present disclosure; and

FIG. 8B is a schematic cross-sectional view of the electronic device taken along line A-A′ and line B-B′ of FIG. 8A.

### DETAILED DESCRIPTION OF EMBODIMENT

The implementation of the present disclosure is illustrated by specific embodiments to enable persons skilled in the art to easily understand the other advantages and effects of the present disclosure by referring to the disclosure contained therein. The present disclosure is implemented or applied by other different, specific embodiments. Various modifications and changes can be made in accordance with different viewpoints and applications to details disclosed herein without departing from the spirit of the present disclosure.

It should be noted that, in the specification and claims, unless otherwise specified, having “one” element is not limited to having a single said element, but one or more said elements may be provided. Moreover, in the specification and claims, ordinal numbers, such as “first” and “second”, used herein are intended to distinguish elements rather than disclose explicitly or implicitly that names of the elements bear the wording of the ordinal numbers. The ordinal numbers do not imply what order an element and another element are in terms of space, time or steps of a manufacturing method. Thus, the use of these ordinals is only to clearly distinguish a claimed element with a certain name from another claimed element with the same name.

In the entire specification and appended claims of the present disclosure, certain words are used to refer to specific components. Those skilled in the art should understand that electronic device manufacturers may refer to the same components by different names. The present disclosure does not intend to distinguish those components with the same function but different names. In the following description and claims, words such as “comprising”, “including”, and “having” are open type words, so they should be interpreted as meaning “including but not limited to . . . ”. Therefore, when the terms “comprising”, “including” and/or “having” are used in the description of the present disclosure, they specify the existence of corresponding features, regions, steps, operations and/or components, but do not exclude the existence of one or more corresponding features, regions, steps, operations and/or components.

In addition, in the specification and claims, the terms “almost”, “about”, “approximately” or “substantially” usually means within 10%, 5%, 3%, 2%, 1% or 0.5% of a given value or range. The quantity given here is an approximate quantity; that is, without specifying “almost”, “about”, “approximately” or “substantially”, it can still imply the meaning of “almost”, “about”, “approximately” or “substantially”. In addition, the term “range of the first value to the second value” or “range between the first value and the second value” indicates that the range includes the first value, the second value, and other values in between.

Unless otherwise defined, all terms (including technical and scientific terms) used herein have the same meaning as commonly understood by those skilled in the art related to the present disclosure. It can be understood that these terms, such as those defined in commonly used dictionaries, should be interpreted as having meaning consistent with the relevant technology and the background or context of the present disclosure, and should not be interpreted in an idealized or excessively formal way, unless there is a special definition in the embodiment of the present disclosure.

In addition, relative terms such as “below” or “bottom”, and “above” or “top” may be used in the embodiments to describe the relationship between one component and another component in the drawing. It can be understood that, if the device in the drawing is turned upside down, the components described on the “lower” side will become the components on the “upper” side. When the corresponding member (such as a film or region) is described as “on another member”, it may be directly on the other member, or there may be other members between the two members. On the other hand, when a member is described as “directly on another member”, there is no member between the two members. In addition, when a member is described as “on another member”, the two members have a vertical relationship in the top view direction, and this member may be above or below the other member, while the vertical relationship depends on the orientation of the device.

In the present disclosure, the term “single gate” refers to a transistor having only one gate. The term “double gate” refers to a transistor having two gates respectively disposed on two sides of a semiconductor. The term “dual gate” refers to a transistor having two gates disposed on the same side of a semiconductor.

It should be understood that, according to the disclosed embodiments, an optical microscope (OM), a scanning electron microscope (SEM), a film thickness profilometer (α-step), an ellipsometer thickness gauge, or other suitable means may be used to measure the depth, thickness, width or height of each component, or the distance between components. According to some embodiments, a scanning electron microscope may be used to obtain a cross-sectional structure image including the components to be measured, and measure the depth, thickness, width or height of each component, or the distance between components. In addition, any two values or directions used for comparison may have certain errors. If the first value is equal to the second value, it implies that there may be an error of about 10% between the first value and the second value. If the first direction is perpendicular to the second direction, the angle between the first direction and the second direction may be in a range of 80 to 100 degrees. If the first direction is parallel to the second direction, the angle between the first direction and the second direction may be in a range of 0 to 10 degrees.

In the present disclosure, the electronic device may include a display device, a backlight device, an antenna device, a sensing device or a tiled device, but not limited thereto. The electronic device may be a bendable or flexible electronic device. The display device may be a non-self-luminous display device or a self-luminous display device. In addition, the display device may include a general display device, an augmented reality (AR) display device, a virtual reality (VR) display device, or a mixed reality (MR) display device. The antenna device may be a liquid crystal type antenna device or a non-liquid crystal type antenna device, and the sensing device may be a sensing device that senses capacitance, light, heat energy, or ultrasound, but not limited thereto. The electronic components may include passive components and active components, such as capacitors, resistors, inductors, diodes, transistors, etc. The diode may include a light emitting diode or a photodiode. The light emitting diode may include, for example, an organic light emitting diode (OLED), a sub-millimeter light emitting diode (mini LED), a micro LED, or a quantum dot LED, but not limited thereto. The tiled device may be, for example, a display tiled device or an antenna tiled device, but not limited thereto. It should be noted that the electronic device may be any arrangement or combination of the aforementioned, but not limited thereto.

In addition, the shape of the electronic device may be a rectangular shape, a circular shape, a polygonal shape, a shape with curved edges, or other suitable shapes. The electronic device may have peripheral systems such as drive system, operating system, light source system, shelf system, etc. to support the display device or tiled device.

It should be noted that the technical solutions provided by the different embodiments described hereinafter may be used interchangeably, combined or mixed to form another embodiment without violating the spirit of the present disclosure.

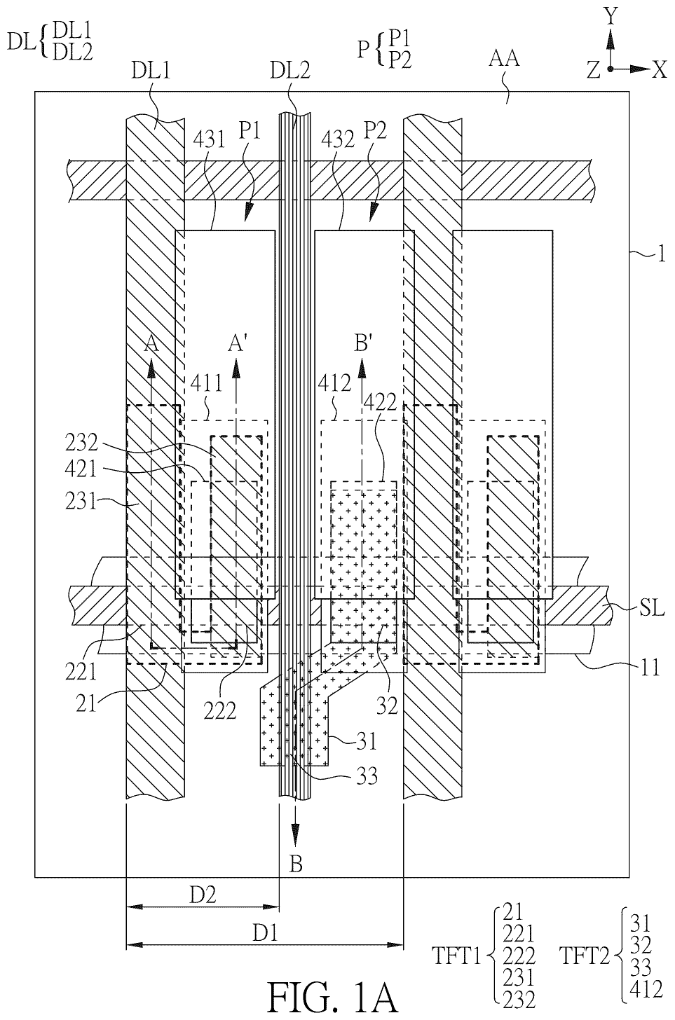

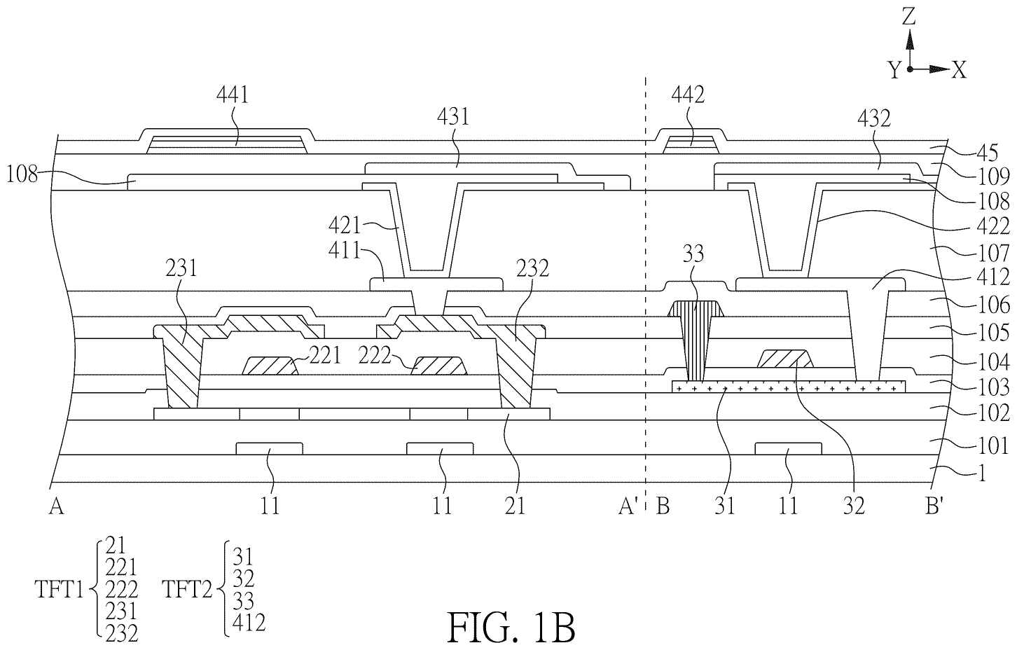

FIG. 1A is a schematic top view of a portion of an electronic device according to an embodiment of the present disclosure, and FIG. 1B is a schematic cross-sectional view of the electronic device taking along line A-A′ and line B-B′ of FIG. 1A, wherein, for the convenience of explanation, some components are omitted in the figures.

In one embodiment of the present disclosure, as shown in FIG. 1A and FIG. 1B, the electronic device may include: a substrate 1 having an active area AA; a plurality of scan lines SL disposed on the substrate 1 and extending along a first direction X; a plurality of data lines DL disposed on the substrate 1 and extending along a second direction Y, the second direction Y being perpendicular to the first direction X, wherein the scan lines SL and the data lines DL are intersected to form a plurality of pixels P, and the pixels P are arranged in an array and disposed in the active area AA; a plurality of first transistors TFT1 arranged respectively corresponding to the pixels P (for example, the first pixels P1) of the active area AA, wherein each of the first transistors TFT1 includes a first semiconductor 21; a plurality of second transistor TFT2 arranged respectively corresponding to the pixels P (for example, the second pixels P2) of the active area AA, and alternately arranged with the first transistor TFT1 in the first direction X, wherein each of the second transistors TFT2 includes a second semiconductor 31. The first semiconductor 21 has a material different from that of the second semiconductor 31, and in the first direction X, the distance D1 between two adjacent first semiconductors 21 is greater than the distance D2 between two adjacent data lines DL.

In the present disclosure, the material of the first semiconductor 21 of the first transistor TFT1 is designed to be different from the material of the second semiconductor 31 of the second transistor TFT2, and the first transistor TFT1 and the second transistor TFT2 are arranged alternately in the first direction X, so that the distance D1 between two adjacent first semiconductors 21 may be greater than the distance D2 between two adjacent data lines DL. As a result, the density of components within a unit area may be increased (for example, the number of pixels P within a unit area may be increased), thereby improving the resolution of the display device. The “distance between two adjacent first semiconductors” refers to, for example, a distance between the same sides of two adjacent first semiconductors 21 in the first direction X. The “distance between two adjacent data lines” refers to, for example, the distance between the same sides of two adjacent data lines DL in the first direction X, or refers to, for example, the distance between the same sides of the adjacent first data line DL1 and second data line DL2 in the first direction X.

In one embodiment of the present disclosure, as shown in FIG. 1A and FIG. 1B, the electronic device may include: a buffer layer 101 disposed on the substrate 1; a first semiconductor 21 disposed on the buffer layer 101; a first gate insulation layer 102 disposed on the first semiconductor 21; a second semiconductor 31 disposed on the first gate insulation layer 102; a second gate insulation layer 103 disposed on the second semiconductor 31; a first metal layer disposed on the second gate insulation layer 103, wherein the first metal layer includes scan lines SL, two first gates 221, 222 and a second gate 32; a first insulation layer 104 disposed on the first metal layer; a second metal layer disposed on the first insulation layer 104, wherein the second metal layer includes a first data line DL1, a first electrode 231 and a second electrode 232, and the first electrode 231 and the second electrode 232 are each electrically connected to the first semiconductor 21; a second insulation layer 105 disposed on the second metal layer; a third metal layer disposed on the second insulation layer 105, wherein the third metal layer includes a second data line DL2 and a first electrode 33, and the first electrode 33 is electrically connected to the second semiconductor 31; a third insulation layer 106 disposed on the third metal layer; a first conductive layer disposed on the third insulation layer 106, wherein the first conductive layer includes a first conductive portion 411 and a second electrode 412, the first conductive portion 4 11 is electrically connected to the second electrode 232 of the first transistor TFT1, and the second electrode 412 of the second transistor TFT2 is electrically connected to the second semiconductor 31; a first planarization layer 107 disposed on the first conductive layer; a second conductive layer disposed on the first planarization layer 107, wherein the second conductive layer includes a first portion 421 and a second portion 422, the first portion 421 is electrically connected to the first conductive portion 411 via a through hole, and the second portion 422 is electrically connected to the second electrode 412 via a through hole; a second planarization layer 108 disposed on the second conductive layer; a third conductive layer disposed on the first planarization layer 107, the second conductive layer and the second planarization layer 108, wherein the third conductive layer includes a third portion 431 and a fourth portion 432, the third portion 431 is electrically connected to the first portion 421 of the second conductive layer, and the fourth portion 432 is electrically connected to the second portion 422 of the second conductive layer; a fourth insulation layer 109 disposed on the third conductive layer; a fourth metal layer disposed on the fourth insulation layer 109, wherein the fourth metal layer includes a first portion 441 and a second portion 442, the first portion 441 of the fourth metal layer overlaps with a portion of the second metal layer in the top-view direction Z of the substrate 1, and the second portion 442 of the fourth metal layer overlaps with a portion of the third metal layer; and a fourth conductive layer 45 disposed on the fourth insulation layer 109 and the fourth metal layer. The first transistor TFT1 includes a first semiconductor 21, first gates 221 and 222, a first electrode 231 and a second electrode 232. The first electrode 231 and the second electrode 232 are each electrically connected to the first semiconductor 21. The second transistor TFT2 includes a second semiconductor 31, a second gate 32, a first electrode 33 and a second electrode 412. The first electrode 33 and the second electrode 412 are each electrically connected to the second semiconductor 31.

In the present disclosure, the substrate 1 may be a flexible substrate or a rigid substrate. The material of the substrate 1 may be glass, quartz, sapphire, ceramic, plastic, polycarbonate (PC), polyimide (PI), polypropylene (PP), polyethylene terephthalate (PET), polymethylmethacrylate (PMMA), other suitable materials or a combination of the above materials, but the present disclosure is not limited thereto. In the present disclosure, the first semiconductor 21 may include a silicon semiconductor, such as amorphous silicon or polycrystalline silicon (for example, low temperature polycrystalline silicon (LTPS)), but the present disclosure is not limited thereto. The second semiconductor 31 may include an oxide semiconductor, such as a metal oxide (for example, indium gallium zinc oxide (IGZO), indium gallium oxide (IGO), indium tin zinc oxide (ITZO), or indium gallium tin zinc oxide (IGTZO), but the present disclosure is not limited thereto. In one embodiment of the present disclosure, the first semiconductor 21 includes low temperature polysilicon (LTPS), and the second semiconductor 31 includes indium gallium zinc oxide (IGZO). In one embodiment of the present disclosure, the first semiconductor 21 may include doped carriers, such as N-type carriers or P-type carriers, to form an N-doped semiconductor or a P-doped semiconductor, but the present disclosure is not limited thereto. By designing the adjacent semiconductors (that is, the first semiconductor 21 and the second semiconductor 31) to be formed of different materials, the distance between the adjacent semiconductors may be reduced, thereby overcoming the process limitation or improving the device density.

In the present disclosure, the buffer layer 101, the first gate insulation layer 102, the second gate insulation layer 103, the first insulation layer 104, the second insulation layer 105, the third insulation layer 106, the first planarization layer 107, the second planarization layer 108 and the fourth insulation layer 109 may each include a single layer or a multi-layer structure, and the materials of the buffer layer 101, the first gate insulation layer 102, the second gate insulation layer 103, the first insulation layer 104, the second insulation layer 105, the third insulation layer 106, the first planarization layer 107, the second planarization layer 108 and the fourth insulation layer 109 may each include silicon nitride, silicon oxide, silicon oxynitride, silicon carbonitride, aluminum oxide, organic material or a combination thereof, but the present disclosure is not limited thereto. The suitable organic material includes acrylic acid, polyimide, benzocyclobutene-based resin, acrylate-based resin, or a combination thereof, but the present disclosure is not limited thereto.

In the present disclosure, the first metal layer, the second metal layer, the third metal layer and the fourth metal layer may each include a single layer or a multi-layer structure, and the first metal layer, the second metal layer, the third metal layer and the fourth metal layer may each include a metal material, an alloy thereof or a combination thereof. The suitable metal material may be, for example, gold, silver, copper, palladium, platinum, ruthenium, aluminum, cobalt, nickel, titanium, molybdenum, manganese, and tungsten, but the present disclosure is not limited thereto. In some embodiments, the first metal layer, the second metal layer, the third metal layer and the fourth metal layer may each include metal oxide or metal nitride, such as aluminum nitride, titanium nitride, copper nitride, molybdenum nitride, tungsten nitride, molybdenum oxide and tungsten oxide, but the present disclosure is not limited thereto. In the present disclosure, the first conductive layer, the second conductive layer, the third conductive layer and the fourth conductive layer may each include a transparent conductive material, such as indium zinc oxide (IZO), indium tin oxide (ITO), indium tin zinc oxide (ITZO), indium gallium zinc oxide (IGZO) or aluminum zinc oxide (AZO), but the present disclosure is not limited thereto. In one embodiment of the present disclosure, the first conductive layer, the second conductive layer, the third conductive layer, and the fourth conductive layer may each include indium tin oxide (ITO). In the present disclosure, since the second electrode 412 of the second transistor TFT2 is made of a transparent conductive material, the aperture ratio of the corresponding pixel P (for example, the second pixel P2) may be increased, thereby achieving a power saving effect.

In one embodiment of the present disclosure, the electronic device may include a light shielding layer 11 disposed on the substrate 1, wherein the light shielding layer 11 is disposed corresponding to the first semiconductor 21 and the second semiconductor 31, respectively. The light shielding layer 11 may be used to prevent light-induced leakage current or light-induced instability of the first transistor TFT1 and/or the second transistor TFT2. The light shielding layer 11 may also be used to prevent hydrogen ions from diffusing and causing degradation of the first semiconductor 21 and/or the second semiconductor 31. In the present disclosure, the material of the light shielding layer 11 may include a low light transmittance material, such as metal, black matrix or other suitable materials, but the present disclosure is not limited thereto. In some embodiments, when the material of the light shielding layer 11 is metal, the light shielding layer 11 may also serve as a bottom gate.

In one embodiment of the present disclosure, as shown in FIG. 1A and FIG. 1B, the first transistor TFT1 may have a dual gate structure. For example, the first transistor TFT1 has two first gate electrodes 221 and 222, and is electrically connected to one of the scan lines SL. In one embodiment of the present disclosure, as shown in FIG. 1B, the first transistor TFT1 and the second transistor TFT2 each may be a top gate structure. For example, the two first gates 221 and 222 of the first transistor TFT1 are respectively disposed on the first semiconductor 21, and the second gate 32 of the second transistor TFT2 is disposed on the second semiconductor 31. However, the present disclosure is not limited to the above structure. In other embodiments, the first gates 221, 222 and the second gate 32 may be adjusted to a single gate structure, a double gate structure or a dual gate structure as needed. The first gates 221, 222 and the second gate 32 may also be selectively adjusted to a bottom gate structure as needed.

In one embodiment of the present disclosure, as shown in FIG. 1A and FIG. 1B, two adjacent data lines DL may be disposed in different layers (that is, formed of different metal layers). In more detail, the data lines DL may include a first data line DL1 and a second data line DL2, the first data line DL1 and the second data line DL2 are disposed adjacent to each other, and the first data line DL1 and the second data line DL2 are disposed in different layers (for example, the first data line DL1 may be formed of the second metal layer, and the second data line DL2 may be formed of the third metal layer, but it is not limited thereto), wherein one of the first transistors TFT1 may be electrically connected to the first data line DL1, and one of the second transistors TFT2 may be electrically connected to the second data line DL2. By designing adjacent data lines DL to be formed of different metal layers, the spacing between adjacent data lines DL may be reduced, thereby overcoming process limitations, improving process yield, or increasing device density.

In one embodiment of the present disclosure, as shown in FIG. 1B, the first transistor TFT1 may be electrically connected to the third portion 431 of the third conductive layer through the first conductive portion 411 of the first conductive layer and the first portion 421 of the second conductive layer, thereby transmitting the signal of the first transistor TFT1 to the third portion 431 of the third conductive layer. Similarly, the second transistor TFT2 may be electrically connected to the fourth portion 432 of the third conductive layer through the second portion 422 of the second conductive layer, so that the signal of the second transistor TFT2 is transmitted to the fourth portion 432 of the third conductive layer. By applying voltage to the third conductive layer and the fourth conductive layer 45, the arrangement of the liquid crystal material (not shown) in the display medium layer (not shown) is controlled, so that an image is displayed.

In one embodiment of the present disclosure, as shown in FIG. 1B, in the top-view direction Z of the substrate 1, the projections of the first gates 221, 222 and the second gate 32 on the substrate 1 may substantially overlap with the projection of the light shielding layer 11 on the substrate 1. In one embodiment of the present disclosure, in the top-view direction Z of the substrate 1, the projection of the fourth metal layer on the substrate 1 may substantially overlap with the projection of the data line DL (as shown in FIG. 1A) on the substrate 1, and the fourth metal layer may serve as a light shielding unit. In the present disclosure, although not shown in the figures, the electronic device may further include: a counter substrate disposed opposite to the substrate 1; and a display medium layer disposed between the substrate 1 and the counter substrate. The material of the counter substrate is similar to that of the substrate 1 and will not be described in detail here. The display medium layer may include a liquid crystal material, and the suitable liquid crystal material includes, for example, polymer stabilized cholesteric texture (PSCT), polymer dispersed liquid crystal (PDLC), polymer network liquid crystal (PNLC), other suitable liquid crystal materials or a combination thereof, but the present disclosure is not limited thereto. In addition, the electronic device may further include other components such as an alignment layer, a polarizer, a backlight module and/or a driving component, which will not be described in detail here.

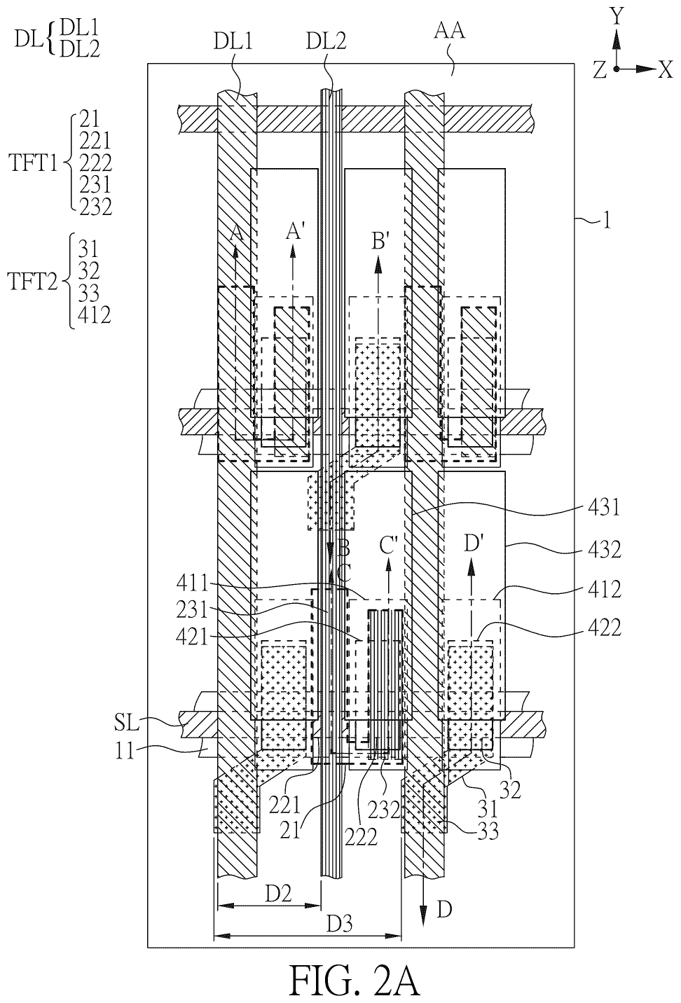

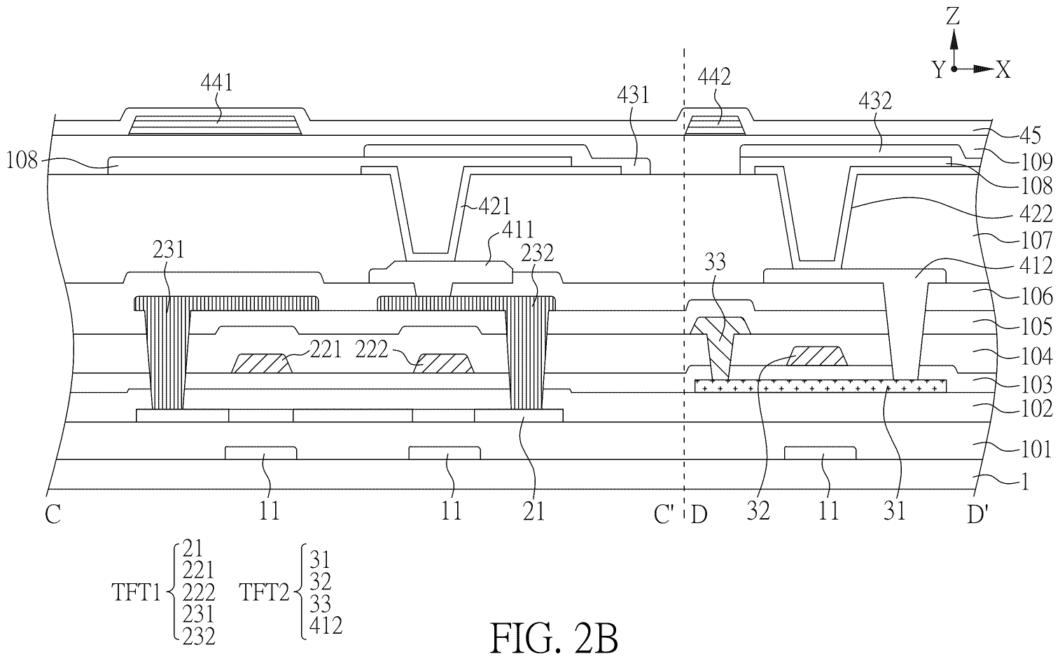

FIG. 2A is a schematic top view of a portion of an electronic device according to an embodiment of the present disclosure, and FIG. 2B is a schematic cross-sectional view of the electronic device taken along line C-C′ and line D-D′ of FIG. 2A, wherein the electronic device of FIG. 2A is similar to that of FIG. 1A except for the following differences. In addition, the cross-sectional schematic diagram of the electronic device taken along line A-A′ and line B-B′ of FIG. 2A may be shown as in FIG. 1B. For the convenience of explanation, some components are omitted in the figures.

In one embodiment of the present disclosure, as shown in FIG. 2A, the second transistor TFT2 and the first transistor TFT1 are arranged alternately in the first direction X, and the second transistor TFT2 and the first transistor TFT1 are arranged alternately in the second direction Y. Therefore, in a cross-sectional view, as shown in FIG. 2B, a portion of the first electrode 231 and the second electrode 232 of the first transistor TFT1 may be formed of the third metal layer, and a portion of the first electrode 33 of the second transistor TFT2 may be formed of the second metal layer.

In one embodiment of the present disclosure, as shown in FIG. 2A, one of the first transistors TFT1 may be electrically connected to the second data line DL2, and one of the second transistors TFT2 may be electrically connected to the first data line DL1. In the present disclosure, in the first direction X, a distance D3 between two adjacent second semiconductors 31 may be greater than a distance D2 between two adjacent data lines DL. As a result, the density of components within a unit area may be increased (for example, the number of pixels within a unit area may be increased), thereby improving the resolution of the display device. The “distance between two adjacent second semiconductors” refers to, for example, a distance between the same sides of two adjacent second semiconductors 31 in the first direction X.

In the present disclosure, other features of component, material and so on of the electronic device may be as described above and will not be repeated here.

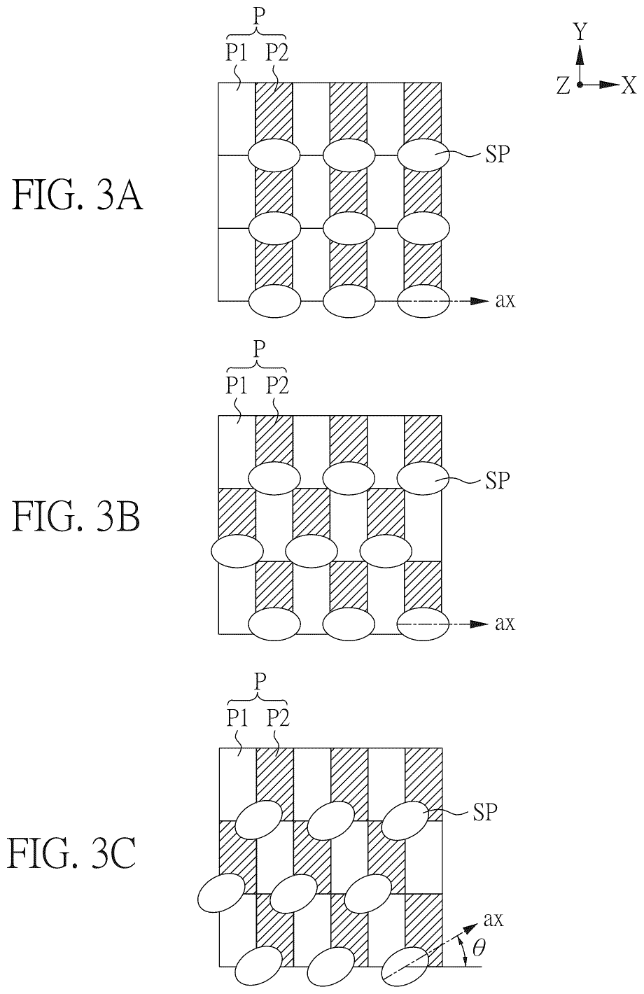

FIG. 3A to FIG. 3C are schematic diagrams of a portion of an electronic device according to an embodiment of the present disclosure. In the figures, a blank pattern represents a pixel having a first transistor TFT1 (for example, a first pixel P1), and a filled pattern represents a pixel having a second transistor TFT2 (for example, a second pixel P2), wherein the first transistor TFT1 and the second transistor TFT2 may be any one of those described in FIG. 1A to FIG. 2B.

In one embodiment of the present disclosure, as shown in FIG. 3A to FIG. 3C, a plurality of pixels P are arranged in an array and include a first pixel P1 and a second pixel P2, wherein the first pixel P1 includes a first transistor TFT1 (as shown in FIG. 1A to FIG. 2B), and the second pixel P2 includes a second transistor TFT2 (as shown in FIG. 1A to FIG. 2B), and the first transistor TFT1 and the second transistor TFT2 are alternately arranged in a first direction X. In one embodiment of the present disclosure, compared with an electronic device including only the first transistors TFT1, the aperture ratio of the electronic device may be increased by more than 10%, for example, by about 20% or 30%, through designing the first transistor TFT1 and the second transistor TFT2 to be alternately arranged in the first direction X, but the present disclosure is not limited thereto.

In one embodiment of the present disclosure, as shown in FIG. 3B and FIG. 3C, the first pixel P1 and the second pixel P2 are arranged alternately in the first direction X, and the first pixel P1 and the second pixel P2 are arranged alternately in the second direction Y. As a result, the display quality of the electronic device can be improved.

In one embodiment of the present disclosure, as shown in FIG. 3A to FIG. 3C, the electronic device further includes a plurality of spacers SP, each disposed corresponding to the second pixel P2. In more detail, the spacer SP has a projection in the top-view direction Z of the electronic device, wherein the projection area of the spacer SP in the second pixel P2 may be greater than the projection area of the spacer SP in the first pixel P1. Since the aperture ratio of the second pixel P2 is greater than the aperture ratio of the first pixel P1, when the spacer SP is disposed corresponding to the second pixel P2, the taste effect of the electronic device may be improved. In one embodiment of the present disclosure, the spacers SP may be respectively disposed corresponding to the second transistors TFT2 (as shown in FIG. 1A to FIG. 2B), and the spacers SP may serve as light shielding units.

In FIG. 3A to FIG. 3C, elliptical spacers SP are used as examples, but in the present disclosure, the shape of the spacers SP is not particularly limited, and may be, for example, circular, elliptical, rectangular, trapezoidal, irregular, or other suitable shapes. In addition, there is no particular limitation on the arrangement direction of the spacer SP. More specifically, the elliptical spacer SP has a long axis ax, as shown in FIG. 3A and FIG. 3B, the extension direction of the long axis ax may be parallel to the first direction X. Alternatively, as shown in FIG. 3C, the extension direction of the long axis ax may have an angle θ with the first direction X, and the angle θ is approximately 45°, but the present disclosure is not limited thereto. In other embodiments, the angle θ may be between 0° and 180°.

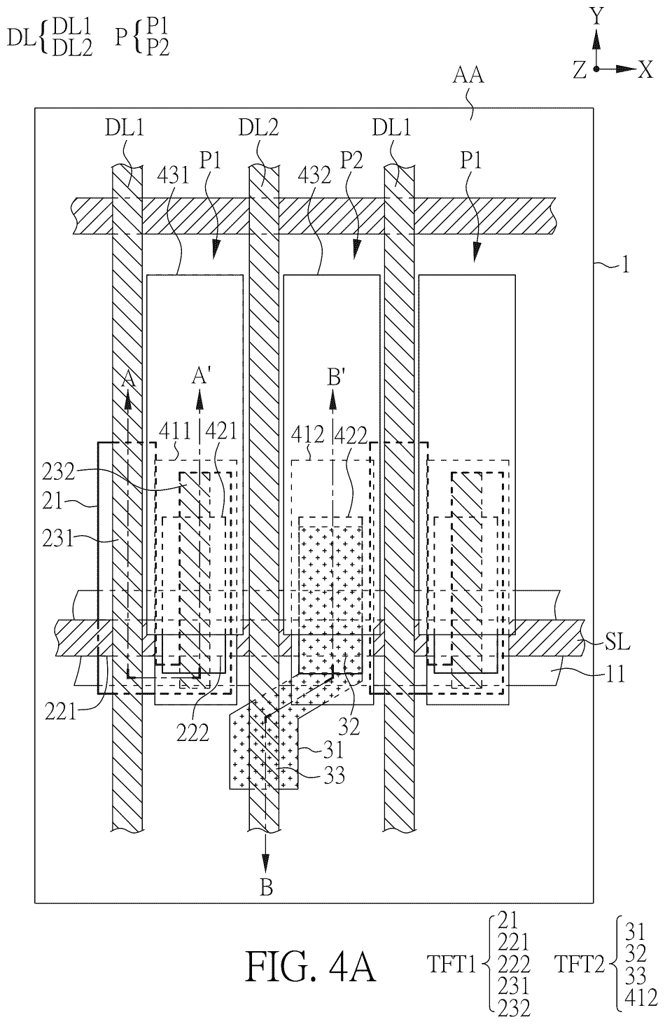

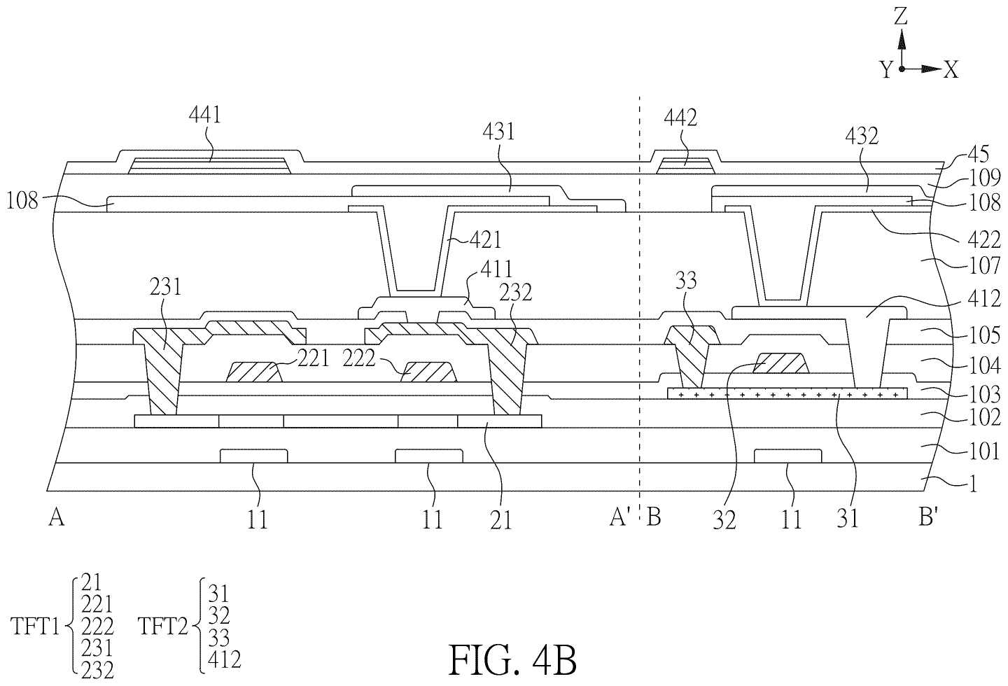

FIG. 4A is a schematic top view of a portion of an electronic device according to an embodiment of the present disclosure, and FIG. 4B is a schematic cross-sectional view of the electronic device taken along line A-A′ and line B-B′ of FIG. 4A, wherein the electronic device of FIG. 4A is similar to that of FIG. 1A, except for the following differences. In addition, some components are omitted in the figures for convenience of explanation.

As shown in FIG. 4A and FIG. 4B, in this embodiment, in the top-view direction Z of the substrate 1, the first semiconductor 21 is U-shaped, the second semiconductor 31 is Z-shaped, and the first semiconductor 21 includes a first portion, a second portion and a third portion. The first portion overlaps with one of the data lines DL (for example, the first data line DL1) and is connected to the second portion, the extension direction of the second portion is substantially parallel to the extension direction of the scan line SL (for example, the first direction X), and a portion of the third portion is disposed in the area of the pixel P (for example, the first pixel P1) and is connected to the second portion, wherein the extension direction of the first portion is substantially parallel to the extension direction of the third portion (for example, parallel to the second direction Y). In some embodiments, the third portion may be disposed in the middle of the area of the pixel P or may be disposed close to the second data line DL2.

In one embodiment of the present disclosure, as shown in FIG. 4A and FIG. 4B, two adjacent data lines DL may be disposed in the same layer (that is, formed of the same metal layer). In more detail, the data lines DL may include a first data line DL1 and a second data line DL2, the first data line DL1 and the second data line DL2 are disposed adjacent to each other, and the first data line DL1 and the second data line DL2 are disposed in the same layer (for example, the first data line DL1 and the second data line DL2 each may be formed of the second metal layer, but it is not limited thereto), wherein one of the first transistors TFT1 may be electrically connected to the first data line DL1, and one of the second transistors TFT2 may be electrically connected to the second data line DL2. As a result, the first data line DL1 and the second data line DL2 may be simultaneously manufactured in the same photo-mask process, thereby achieving the effect of saving cost or simplifying the process. In addition, as shown in FIG. 4B, the first electrode 33 of the second transistor TFT2 may be formed by a second metal layer.

In the present disclosure, other features of component, material and so on of the electronic device may be as described above and will not be repeated here.

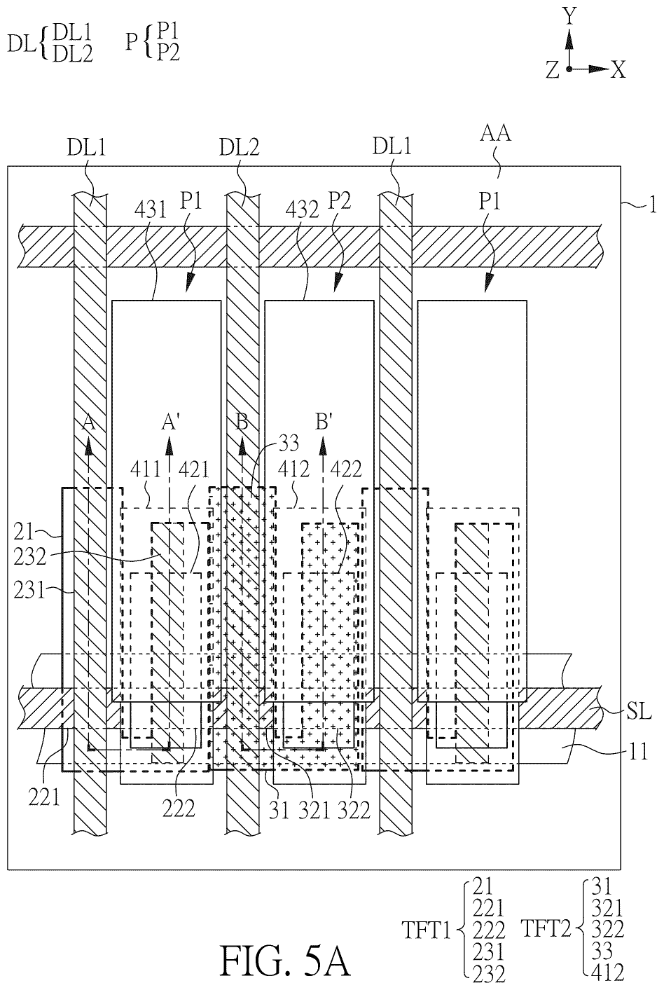

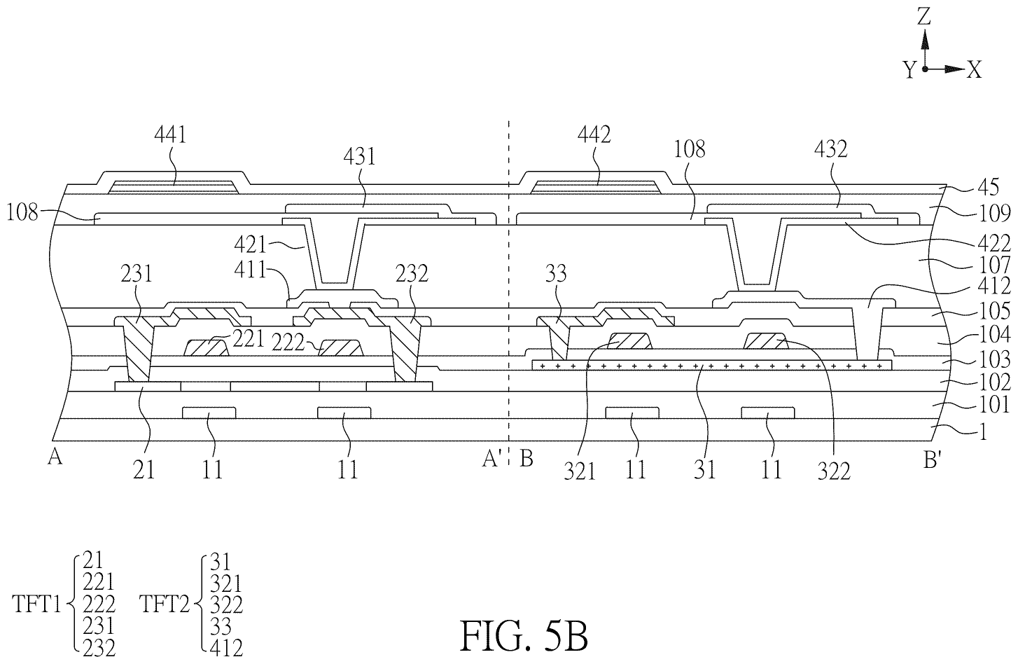

FIG. 5A is a schematic top view of a portion of an electronic device according to an embodiment of the present disclosure, and FIG. 5B is a schematic cross-sectional view of the electronic device taken along line A-A′ and line B-B′ of FIG. 5A, wherein the electronic device of FIG. 5A is similar to that of FIG. 1A, except for the following differences. In addition, some components are omitted in the figures for convenience of explanation.

In one embodiment of the present disclosure, as shown in FIG. 5A and FIG. 5B, the first transistor TFT1 and the second transistor TFT2 each may have a dual gate structure; that is, the first transistor TFT1 has two first gate electrodes 221, 222 and is electrically connected to one of the scan lines SL, and the second transistor TFT2 has two second gate electrodes 321, 322 and is electrically connected to the one of the scan lines SL. In the present disclosure, the two first gates 221, 222 of the first transistor TFT1 and the two second gates 321, 322 of the second transistor TFT2 may be formed of the first metal layer, so that they may be manufactured simultaneously in the same photo-mask process, thereby achieving the effect of saving costs or simplifying the process. In one embodiment of the present disclosure, as shown in FIG. 5B, the first transistor TFT1 and the second transistor TFT2 each may be a top gate structure. For example, the two first gates 221 and 222 of the first transistor TFT1 are each disposed on the first semiconductor 21, and the two second gates 321 and 322 of the second transistor TFT2 are each disposed on the second semiconductor 31. However, the present disclosure is not limited to the above structure. In other embodiments, the first gates 221, 222 and the second gates 321, 322 may be adjusted to a single gate structure or a double gate structure as needed. The first gates 221, 222 and the second gates 321, 322 may also be selectively adjusted to a bottom gate structure as needed.

In one embodiment of the present disclosure, as shown in FIG. 5A and FIG. 5B, two adjacent data lines DL may be disposed in the same layer (that is, formed of the same metal layer). In more detail, the data lines DL may include a first data line DL1 and a second data line DL2, the first data line DL1 and the second data line DL2 are adjacent to each other, and the first data line DL1 and the second data line DL2 are disposed in the same layer (for example, the first data line DL1 and the second data line DL2 each may be formed of the second metal layer, but it is not limited thereto), wherein one of the first transistors TFT1 may be electrically connected to the first data line DL1, and one of the second transistors TFT2 may be electrically connected to the second data line DL2. As a result, the first data line DL1 and the second data line DL2 may be simultaneously manufactured in the same photo-mask process, thereby achieving the effect of saving cost or simplifying the process. In addition, as shown in FIG. 5B, the first electrode 33 of the second transistor TFT2 may be formed by a second metal layer.

In the present disclosure, other features of component, material and so on of the electronic device may be as described above and will not be repeated here.

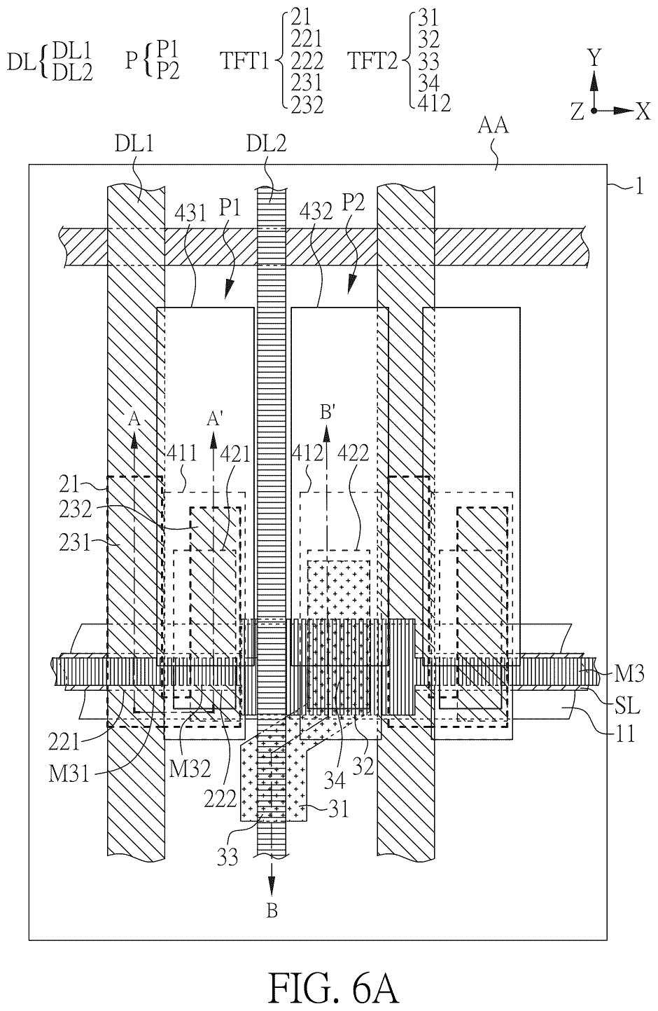

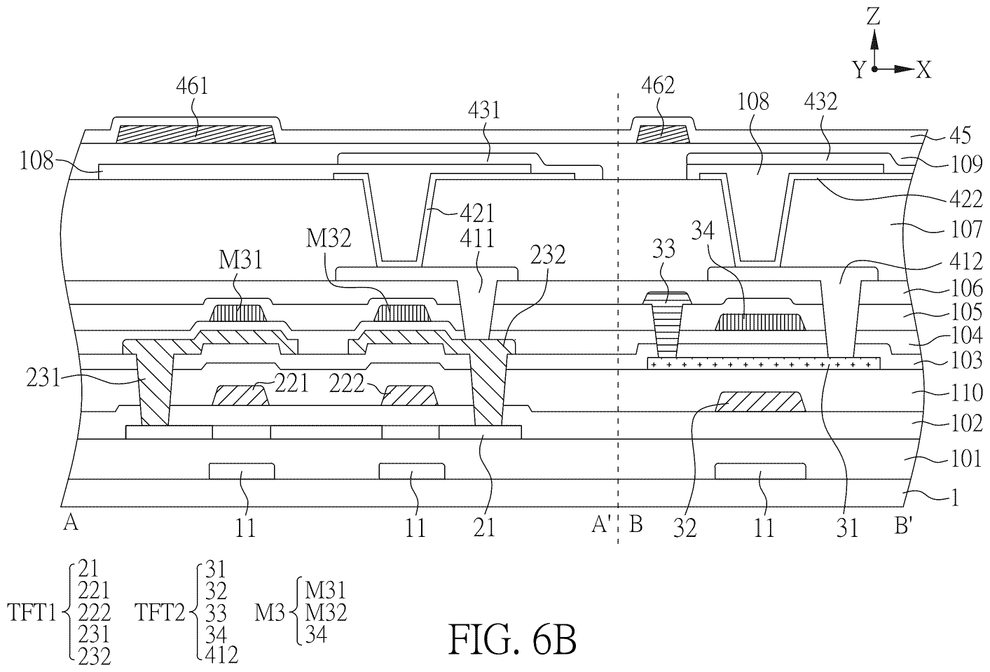

FIG. 6A is a schematic top view of a portion of an electronic device according to an embodiment of the present disclosure, and FIG. 6B is a schematic cross-sectional view of the electronic device taken along line A-A′ and line B-B′ of FIG. 6A, wherein the electronic device of FIG. 6A is similar to that of FIG. 1A, except for the following differences. In addition, some components are omitted in the figures for convenience of explanation.

In one embodiment of the present disclosure, as shown in FIG. 6A and FIG. 6B, the electronic device may include: a buffer layer 101 disposed on the substrate 1; a first semiconductor 21 disposed on the buffer layer 101; a first gate insulation layer 102 disposed on the first semiconductor 21; a first metal layer disposed on the first gate insulation layer 102, wherein the first metal layer includes scan lines SL, two first gates 221, 222 and a second gate 32; a third gate insulation layer 110 disposed on the first metal layer; a second semiconductor 31 disposed on the third gate insulation layer 110; a second gate insulation layer 103 disposed on the second semiconductor 31; a second metal layer disposed on the second gate insulation layer 103, wherein the second metal layer includes a first data line DL1, a first electrode 231 and a second electrode 232, and the first electrode 231 and the second electrode 232 are each electrically connected to the first semiconductor 21; a first insulation layer 104 disposed on the second metal layer; a third metal layer M3 disposed on the first insulation layer 104, wherein the third metal layer M3 includes a first portion M31, a second portion M32 and a third gate 34; a second insulation layer 105 disposed on the third metal layer M3; a fourth metal layer disposed on the second insulation layer 105, wherein the fourth metal layer includes a second data line DL2 and a first electrode 33, and the first electrode 33 is electrically connected to the second semiconductor 31; a third insulation layer 106 disposed on the fourth metal layer; a first conductive layer disposed on the third insulation layer 106, wherein the first conductive layer includes a first conductive portion 411 and a second electrode 412, the first conductive portion 411 is electrically connected to the second electrode 232 of the first transistor TFT1, and the second electrode 412 of the second transistor TFT2 is electrically connected to the second semiconductor 31; a first planarization layer 107 disposed on the first conductive layer; a second conductive layer disposed on the first planarization layer 107, wherein the second conductive layer includes a first portion 421 and a second portion 422, the first portion 421 is electrically connected to the first conductive portion 411 via a through hole, and the second portion 422 is electrically connected to the second electrode 412 via a through hole; a second planarization layer 108 disposed on the second conductive layer; a third conductive layer disposed on the first planarization layer 107, the second conductive layer, and the second planarization layer 108, wherein the third conductive layer includes a third portion 431 and a fourth portion 432, the third portion 431 is electrically connected to the first portion 421 of the second conductive layer, and the fourth portion 432 is electrically connected to the second portion 422 of the second conductive layer; a fourth insulation layer 109 disposed on the third conductive layer; a fifth metal layer disposed on the fourth insulation layer 109, wherein the fifth metal layer includes a first portion 461 and a second portion 462, and the first portion 461 of the fifth metal layer overlaps with a portion of the second metal layer and the second portion 462 of the fifth metal layer overlaps with a portion of the fourth metal layer in the top-view direction Z of the substrate 1; and a fourth conductive layer 45 disposed on the fourth insulation layer 109 and the fifth metal layer. The first semiconductor 21, the first gate electrodes 221 and 222, the first electrode 231 and the second electrode 232 may form a first transistor TFT1. The second semiconductor 31, the second gate 32, the third gate 34, the first electrode 33 and the second electrode 412 may form a second transistor TFT2.

Therefore, in this embodiment, the second transistor TFT2 may have a double gate structure. In more detail, the second transistor TFT2 includes a second gate 32 and a third gate 34. The second gate 32 is arranged under the second semiconductor 31 and is electrically connected to one of the scan lines SL. The third gate 34 is arranged on the second semiconductor layer 31 and corresponds to the second gate 32. When the second transistor TFT2 has the double gate structure, the stability of the second transistor TFT2 may be improved, and the second gate 32 of the second transistor TFT2 may be used to prevent the second semiconductor 31 from being degraded due to the diffusion of hydrogen ions. In some embodiments, since the second gate 32 may be used to reduce the possibility of hydrogen ion diffusion, the second transistor TFT2 may not be provided with the light shielding layer 11, but the present disclosure is not limited thereto.

In one embodiment of the present disclosure, as shown in FIG. 6A and FIG. 6B, the second gate 32 may be formed of a first metal layer, and the third gate 34 may be formed of a third metal layer M3, but the present disclosure is not limited thereto. In one embodiment of the present disclosure, in the top-view direction Z of the substrate 1, the third metal layer M3 may substantially overlap with the first metal layer. More specifically, the projection of a first portion M31 of the third metal layer M3 on the substrate 1 may substantially overlap with the projection of the first gate 221 on the substrate 1, the projection of a second portion M32 of the third metal layer M3 on the substrate 1 may substantially overlap with the projection of the first gate 222 on the substrate 1, and the projection of the third gate 34 on the substrate 1 may substantially overlap with the projection of the second gate 32 on the substrate 1. As a result, the third metal layer M3 and the first metal layer may share the same photo-mask process, thereby achieving the effect of saving cost or simplifying the process. In one embodiment of the present disclosure, in the top-view direction Z of the substrate 1, the projection of the fifth metal layer on the substrate 1 may substantially overlap with the projection of the data line DL on the substrate 1, and the fifth metal layer may serve as a light shielding unit. In this embodiment, the width of the third gate 34 of the second transistor TFT2 may be greater than the width of the first portion M31 of the third metal layer M3, and the width of the third gate 34 of the second transistor TFT2 may be greater than the width of the second portion M32 of the third metal layer M3, so that the performance of the second transistor TFT2 is closer to the performance of the first transistor TFT1, but it is not limited thereto. In one embodiment of the present disclosure, when the width of the gate of the second transistor TFT2 (for example, the second gate 32 and/or the third gate 34) is designed to be greater than the width of the gate of the first transistor TFT1 (for example, the first gates 221, 222), the performance of the second transistor TFT2 may be more consistent with the performance of the first transistor TFT1. The “width of a component” refers to the maximum width of the component in the second direction Y, for example.

In one embodiment of the present disclosure, as shown in FIG. 6A and FIG. 6B, two adjacent data lines DL may be disposed in different layers (that is, formed of different metal layers). In more detail, the first data line DL1 and the second data line DL2 are disposed in different layers (for example, the first data line DL1 may be formed of the second metal layer, and the second data line DL2 may be formed of the fourth metal layer, but it is not limited thereto). By designing adjacent data lines DL to be formed of different metal layers, the spacing between adjacent data lines DL may be reduced, thereby overcoming process limitations, improving process yield, or increasing device density.

In the present disclosure, the first metal layer, the second metal layer, the third metal layer M3, the fourth metal layer and the fifth metal layer may each include a single layer or a multi-layer structure, and the first metal layer, the second metal layer, the third metal layer M3, the fourth metal layer and the fifth metal layer may each include a metal material, an alloy thereof or a combination thereof. The suitable metal material may be, for example, gold, silver, copper, palladium, platinum, ruthenium, aluminum, cobalt, nickel, titanium, molybdenum, manganese, or tungsten, but the present disclosure is not limited thereto. In some embodiments, the first metal layer, the second metal layer, the third metal layer M3, the fourth metal layer and the fifth metal layer may each include metal oxide or metal nitride, such as aluminum nitride, titanium nitride, copper nitride, molybdenum nitride, tungsten nitride, molybdenum oxide or tungsten oxide, but the present disclosure is not limited thereto. In the present disclosure, the material of the third gate insulation layer 110 may include silicon nitride, silicon oxide, silicon oxynitride, silicon carbonitride, aluminum oxide or a combination thereof, but the present disclosure is not limited thereto. In the present disclosure, other features of component, material and so on of the electronic device may be as described above and will not be described in detail herein.

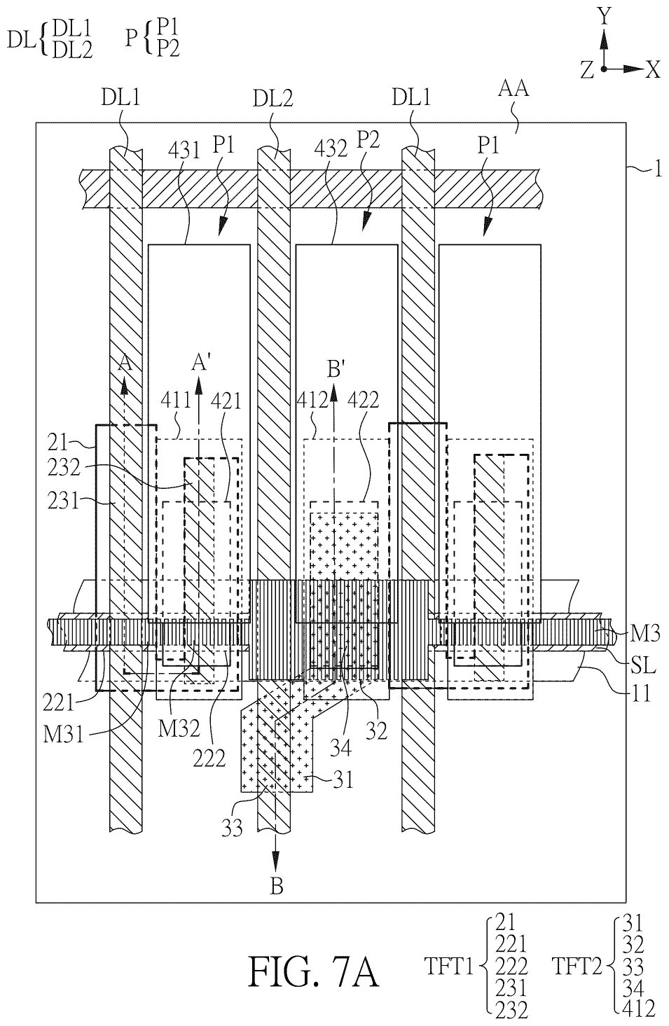

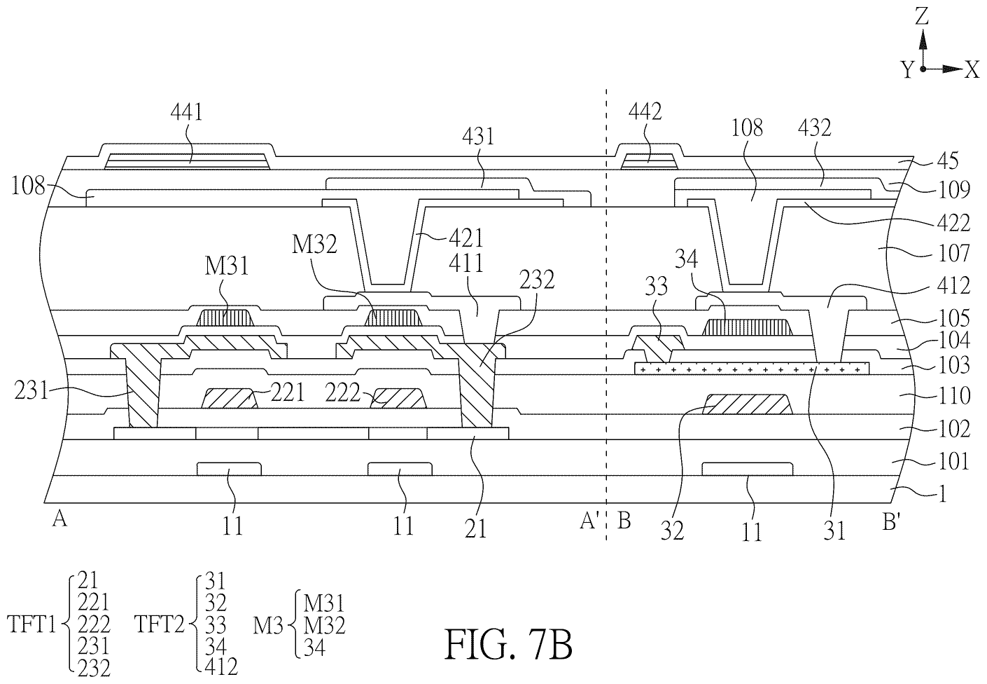

FIG. 7A is a schematic top view of a portion of an electronic device according to an embodiment of the present disclosure, and FIG. 7B is a schematic cross-sectional view of the electronic device taken along line A-A′ and line B-B′ of FIG. 7A, wherein the electronic device in FIG. 7A is similar to that in FIG. 6A. In addition, some components are omitted in the figures for convenience of explanation.

In one embodiment of the present disclosure, as shown in FIG. 7A and FIG. 7B, the second transistor TFT2 may have a double gate structure. In more detail, the second transistor TFT2 may include a second gate 32 and a third gate 34. The second gate 32 is arranged under the second semiconductor 31 and is electrically connected to one of the scan lines SL. The third gate 34 is arranged on the second semiconductor layer 31 and corresponds to the second gate 32. When the second transistor TFT2 has the double gate structure, the stability of the second transistor TFT2 may be improved, and the second gate 32 of the second transistor TFT2 may be used to prevent the second semiconductor 31 from being degraded due to the diffusion of hydrogen ions.

In one embodiment of the present disclosure, as shown in FIG. 7A and FIG. 7B, the second gate 32 may be formed of a first metal layer, and the third gate 34 may be formed of a third metal layer M3, but the present disclosure is not limited thereto. In one embodiment of the present disclosure, the third metal layer M3 may substantially overlap with the first metal layer in the top-view direction Z of the substrate 1. More specifically, the projection of a first portion M31 of the third metal layer M3 on the substrate 1 may substantially overlap with the projection of the first gate 221 on the substrate 1, the projection of a second portion M32 of the third metal layer M3 on the substrate 1 may substantially overlap with the projection of the first gate 222 on the substrate 1, and the projection of the third gate 34 on the substrate 1 may substantially overlap with the projection of the second gate 32 on the substrate 1.

In one embodiment of the present disclosure, as shown in FIG. 7A and FIG. 7B, two adjacent data lines DL may be disposed in the same layer (that is, formed of the same metal layer). In more detail, the data lines DL may include a first data line DL1 and a second data line DL2, the first data line DL1 and the second data line DL2 are adjacent to each other, and the first data line DL1 and the second data line DL2 are disposed in the same layer (for example, the first data line DL1 and the second data line DL2 each may be formed of the second metal layer, but it is not limited thereto), wherein one of the first transistors TFT1 may be electrically connected to the first data line DL1, and one of the second transistors TFT2 may be electrically connected to the second data line DL2. As a result, the first data line DL1 and the second data line DL2 may be simultaneously manufactured in the same photo-mask process, thereby achieving the effect of saving cost or simplifying the process. In addition, as shown in FIG. 7B, the first electrode 33 of the second transistor TFT2 may be formed by a second metal layer.

In the present disclosure, other features of component, material and so on of the electronic device may be as described above and will not be repeated here.

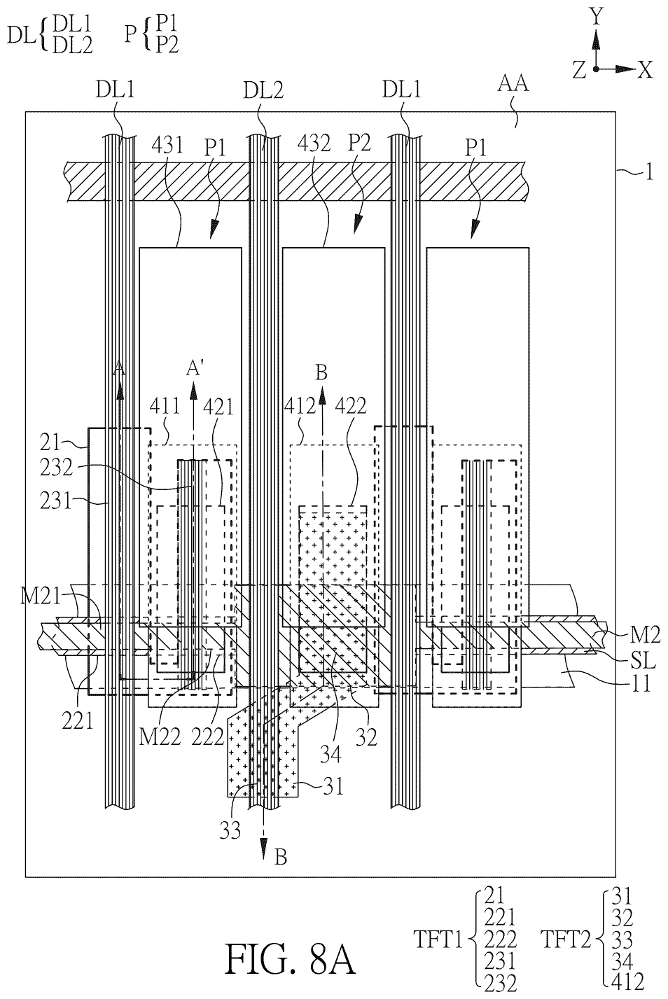

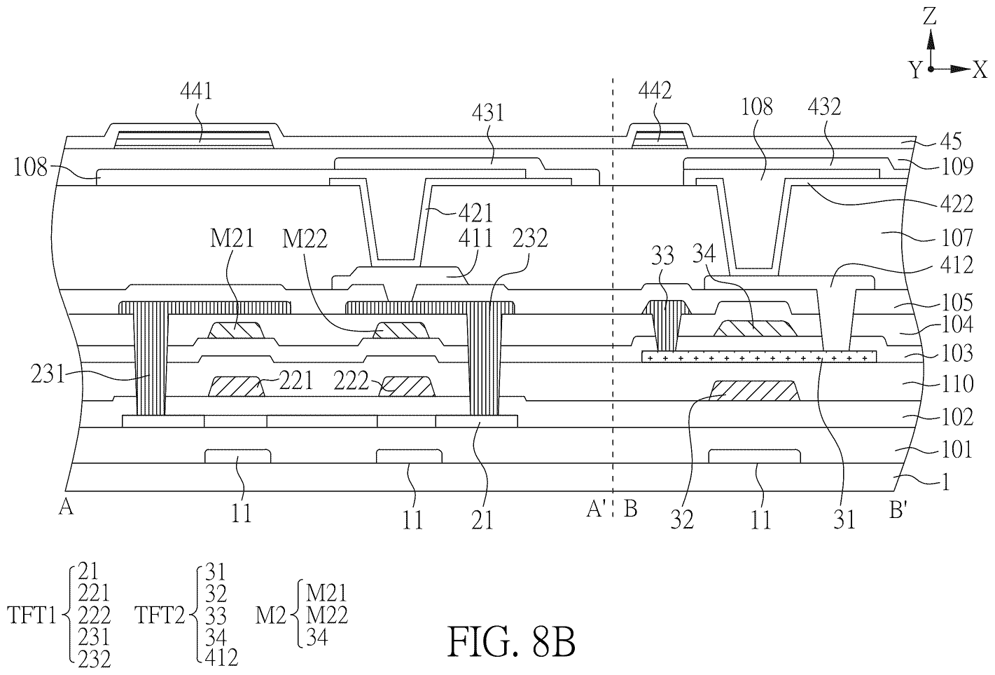

FIG. 8A is a schematic top view of a portion of an electronic device according to an embodiment of the present disclosure, and FIG. 8B is a schematic cross-sectional view of the electronic device taken along line A-A′ and line B-B′ of FIG. 8A, wherein the electronic device of FIG. 8A is similar to that of FIG. 6A, except for the following differences. In addition, some components are omitted in the figures for convenience of explanation.

In one embodiment of the present disclosure, as shown in FIG. 8A and FIG. 8B, the second transistor TFT2 may have a double gate structure. In more detail, the second transistor TFT2 may include a second gate 32 and a third gate 34. The second gate 32 is arranged under the second semiconductor 31 and is electrically connected to one of the scan lines SL. The third gate 34 is arranged on the second semiconductor layer 31 and corresponds to the second gate 32. When the second transistor TFT2 has the double gate structure, the stability of the second transistor TFT2 may be improved, and the second gate 32 of the second transistor TFT2 may be used to prevent the second semiconductor 31 from being degraded due to the diffusion of hydrogen ions. In some embodiments, although not shown in the figures, the second transistor TFT2 may not be provided with a bottom gate (for example, the second gate 32), but the present disclosure is not limited thereto. In some embodiments, although not shown in the figures, the electronic device may not be provided with the light shielding layer 11, but the present disclosure is not limited thereto.

In one embodiment of the present disclosure, as shown in FIG. 8A and FIG. 8B, the second gate 32 may be formed of a first metal layer, and the third gate 34 may be formed of a second metal layer M2, but the present disclosure is not limited thereto. In one embodiment of the present disclosure, in the top-view direction Z of the substrate 1, the second metal layer M2 may substantially overlap with the first metal layer. More specifically, the projection of a first portion M21 of the second metal layer M2 on the substrate 1 may substantially overlap with the projection of the first gate 221 on the substrate 1, the projection of a second portion M22 of the second metal layer M2 on the substrate 1 may substantially overlap with the projection of the first gate 222 on the substrate 1, and the projection of the third gate 34 on the substrate 1 may substantially overlap with the projection of the second gate 32 on the substrate 1.

In one embodiment of the present disclosure, as shown in FIG. 8A and FIG. 8B, two adjacent data lines DL may be disposed in the same layer (that is, formed of the same metal layer). In more detail, the data lines DL may include a first data line DL1 and a second data line DL2, the first data line DL1 and the second data line DL2 are adjacent to each other, and the first data line DL1 and the second data line DL2 are disposed in the same layer (for example, the first data line DL1 and the second data line DL2 each may be formed of a third metal layer, but it is not limited thereto), wherein one of the first transistors TFT1 may be electrically connected to the first data line DL1, and one of the second transistors TFT2 may be electrically connected to the second data line DL2. As a result, the first data line DL1 and the second data line DL2 may be simultaneously manufactured in the same photo-mask process, thereby achieving the effect of saving cost or simplifying the process. In addition, as shown in FIG. 8A and FIG. 8B, the first data line DL1, the second data line DL2, the first electrode 231 and the second electrode 232 of the first transistor TFT1, and the first electrode 33 of the second transistor TFT2 are all formed by the third metal layer. As a result, the load of the data line DL may be reduced, thereby achieving the effect of saving power or improving reliability.

In the present disclosure, other features of component, material and so on of the electronic device may be as described above and will not be repeated here.

In the present disclosure, the adjacent first semiconductor 21 and the second semiconductor 31 are designed to be formed of different materials, and the distance D1 between two adjacent first semiconductors 21 is designed to be greater than the distance D2 between two adjacent data lines DL. As a result, the density of components per unit area may be increased, thereby achieving the effect of improving the resolution of the display device. In addition, when two adjacent data lines DL are disposed in different layers, the interval between the adjacent data lines DL may be reduced, thereby overcoming the process limitation, improving the process yield or increasing the device density.

The aforementioned specific embodiments should be construed as merely illustrative, and not limiting the rest of the present disclosure in any way.

1. An electronic device, comprising:
a substrate having an active area;
a plurality of scan lines disposed on the substrate and extending along a first direction;
a plurality of data lines disposed on the substrate and extending along a second direction perpendicular to the first direction, wherein the scan lines and the data lines are intersected to form a plurality of pixels arranged in an array and disposed in the active area;
a plurality of first transistors respectively disposed corresponding to the pixels of the active area, wherein each of the first transistors includes a first semiconductor; and
a plurality of second transistors respectively disposed corresponding to the pixels of the active area and alternately arranged with the first transistors in the first direction, wherein each of the second transistors includes a second semiconductor,
wherein a material of the first semiconductor is different from a material of the second semiconductor, and a distance between two adjacent first semiconductors is greater than a distance between two adjacent data lines in the first direction.

2. The electronic device as claimed in claim 1, wherein the first semiconductor includes a silicon semiconductor, and the second semiconductor includes an oxide semiconductor.

3. The electronic device as claimed in claim 1, wherein the second transistors and the first transistors are arranged alternately in the second direction.

4. The electronic device as claimed in claim 1, wherein two adjacent ones of the data lines are disposed in different layers.

5. The electronic device as claimed in claim 1, wherein each of the second transistors includes a first electrode and a second electrode, the first electrode and the second electrode are each electrically connected to the second semiconductor, wherein the second electrode includes a transparent conductive material.

6. The electronic device as claimed in claim 1, further comprising a light shielding layer disposed on the substrate, wherein the light shielding layer is disposed corresponding to the first semiconductor and the second semiconductor, respectively.

7. The electronic device as claimed in claim 1, further comprising a plurality of spacers arranged corresponding to the second transistors, respectively.

8. The electronic device as claimed in claim 1, wherein the data lines include a first data line and a second data line disposed adjacent to the first data line, wherein one of the first transistors is electrically connected to the first data line, and one of the second transistors is electrically connected to the second data line.

9. The electronic device as claimed in claim 1, wherein each of the first transistors includes a first gate disposed on the first semiconductor and electrically connected to one of the scan lines, and each of the second transistors includes a second gate disposed under the second semiconductor and electrically connected to one of the scan lines.

10. The electronic device as claimed in claim 9, wherein each of the second transistors includes a third gate disposed on the second semiconductor and corresponding to the second gate.

11. The electronic device as claimed in claim 6, wherein each of the first transistors includes two first gates, a first electrode and a second electrode, the first electrode and the second electrode are each electrically connected to the first semiconductor, and the two first gates are electrically connected to one of the scan lines.

12. The electronic device as claimed in claim 11, wherein, in a top-view direction of the substrate, projections of the two first gates on the substrate overlap with a projection of the light shielding layer on the substrate.

13. The electronic device as claimed in claim 1, wherein, in the first direction, a distance between two adjacent second semiconductors is greater than a distance between two adjacent data lines.

14. The electronic device as claimed in claim 1, further comprising a plurality of spacers respectively arranged corresponding to the pixels disposed with the second transistor, and a projection area of the spacer in the pixel disposed with the second transistor is greater than a projection area of the spacer in the pixel disposed with the first transistor.

15. The electronic device as claimed in claim 1, wherein, in a top-view direction of the substrate, the first semiconductor is U-shaped and the second semiconductor is Z-shaped.

16. The electronic device as claimed in claim 1, wherein the first semiconductor includes a first portion, a second portion and a third portion, the first portion overlaps with one of the data lines and is connected to the second portion, an extension direction of the second portion is parallel to an extension direction of the scan lines, and a portion of the third portion is disposed in an area of one of the pixels disposed with the first transistor and is connected to the second portion, where the extension direction of the first portion is parallel to the extension direction of the third portion.

17. The electronic device as claimed in claim 1, wherein the first transistor has two first gate electrodes and is electrically connected to one of the scan lines, and the second transistor has two second gate electrodes and is electrically connected to the one of the scan lines.

18. The electronic device as claimed in claim 17, wherein two adjacent data lines are disposed in the same layer.

19. The electronic device as claimed in claim 1, wherein each of the second transistors includes a second gate and a third gate, the second gate is disposed under the second semiconductor and is electrically connected to one of the scan lines, and the third gate is disposed on the second semiconductor layer and corresponds to the second gate.

20. The electronic device as claimed in claim 19, wherein two adjacent data lines are disposed in the same layer.
